(19) United States
(12) Patent Application Publication
(10) Pub. No.: US 2025/0329514 A1
(43) Pub. Date: Oct. 23, 2025

(54) CUSTOMIZING ETCH SELECTIVITY AND HIGH ASPECT RATIO FEATURE LOADING THROUGH MULTI-LEVEL PULSING SCHEMES UTILIZING SINUSOIDAL AND CUSTOM RF WAVEFORMS

(71) Applicant: Lam Research Corporation, Fremont, CA (US)

(72) Inventors: Saravanapryan Sriraman, Fremont, CA (US); Alexander Paterson, San Jose, CA (US)

(21) Appl. No.: 18/866,767

(22) PCT Filed: May 25, 2023
(86) PCT No.: PCT/US2023/067483

§ 371 Date: Nov. 18, 2024

Related U.S. Application Data
(60) Provisional application No. 63/348,987, filed on Jun. 3, 2022.

(51) Int. Cl. H01J 37/32

(52) U.S. Cl. CPC H01J 37/32146; H01J 37/32568; H01J 2237/04735; H01J 2237/334

(57) ABSTRACT

A method for performing a plasma etch process in a process chamber is provided, including: applying a source radiofrequency (RF) signal to a top electrode of the process chamber; applying a bias RF signal to a lower electrode of the process chamber; wherein the bias RF signal has two or more pulsed duty cycles, including a first duty cycle having a first sinusoidal waveform at a first frequency and pulsed at a first voltage level, and a second duty cycle having a custom waveform pulsed at a second voltage level, the custom waveform consisting of a second sinusoidal waveform at a second frequency that is combined with a non-sinusoidal waveform.

### FIELD OF THE INVENTION

Implementations of the present disclosure relate to customizing etch selectivity and high aspect ratio feature loading through multi-level pulsing schemes utilizing sinusoidal and custom RF waveforms.

### DESCRIPTION OF THE RELATED ART

In the fabrication of semiconductor devices, reactive ion etching (RIE) is utilized to etch features in substrates (e.g. wafers). However, the demands of modern devices can require etching of high aspect ratio (HAR) features (e.g. height-to-width ratio of greater than 20:1, 30:1, 40:1, 50:1, etc.) for which many challenges remain. Aspect ratio dependent etch (ARDE) is observed in which etch rate declines as the aspect ratio of an etched feature increases. Iso-dense loading is a problem in which etch processing is affected by feature density across a substrate surface.

It is in this context that implementations of the disclosure arise.

### SUMMARY

Implementations of the present disclosure relate to customizing etch selectivity and high aspect ratio feature loading through multi-level pulsing schemes utilizing sinusoidal and custom RF waveforms.

In some implementations, a method for performing a plasma etch process in a process chamber is provided, including: applying a source radiofrequency (RF) signal to a top electrode of the process chamber; applying a bias RF signal to a lower electrode of the process chamber; wherein the bias RF signal has two or more pulsed duty cycles, including a first duty cycle having a first sinusoidal waveform at a first frequency and pulsed at a first voltage level, and a second duty cycle having a custom waveform pulsed at a second voltage level, the custom waveform consisting of a second sinusoidal waveform at a second frequency that is combined with a non-sinusoidal waveform.

In some implementations, the source RF signal is configured to generate a plasma in a plasma process region disposed between the top electrode and the lower electrode.

In some implementations, the bias RF signal is configured to accelerate ions from the plasma towards the lower electrode.

In some implementations, the first duty cycle produces a first ion energy distribution of the ions and, the second duty cycle produces a second ion energy distribution of the ions that is narrower than the first ion energy distribution.

In some implementations, the second voltage level is greater than the first voltage level.

In some implementations, the second frequency is greater than the first frequency.

In some implementations, the top electrode is configured to inductively couple power, or capacitively couple power, into the process chamber.

In some implementations, a method for performing a plasma etch process in a process chamber is provided, including: applying a source radiofrequency (RF) signal to a top electrode of the process chamber; applying a bias RF signal to a lower electrode of the process chamber; wherein the bias RF signal has two or more pulsed duty cycles, including a first duty cycle having a sinusoidal waveform at a first frequency and pulsed at a first voltage level, and a second duty cycle having a non-sinusoidal waveform at a second frequency and pulsed at a second voltage level.

In some implementations, the source RF signal is configured to generate a plasma in a plasma process region disposed between the top electrode and the lower electrode.

In some implementations, the bias RF signal is configured to accelerate ions from the plasma towards the lower electrode.

In some implementations, the first duty cycle produces a first ion energy distribution of the ions and, the second duty cycle produces a second ion energy distribution of the ions that is narrower than the first ion energy distribution.

In some implementations, the second voltage level is greater than the first voltage level.

In some implementations, the second frequency is greater than the first frequency.

In some implementations, the top electrode is configured to inductively couple power, or capacitively couple power, into the process chamber.

In some implementations, a system for performing a plasma etch process is provided, including: a process chamber; a source radiofrequency (RF) generator that generates a source RF signal applied to a top electrode of the process chamber; a plurality of bias RF generators that generate a bias RF signal applied to a lower electrode of the process chamber; wherein the bias RF signal has two or more pulsed duty cycles, including a first duty cycle having a first sinusoidal waveform at a first frequency and pulsed at a first voltage level, and a second duty cycle having a custom waveform pulsed at a second voltage level, the custom waveform consisting of a second sinusoidal waveform at a second frequency that is combined with a non-sinusoidal waveform.

In some implementations, the source RF signal is configured to generate a plasma in a plasma process region disposed between the top electrode and the lower electrode.

In some implementations, the bias RF signal is configured to accelerate ions from the plasma towards the lower electrode.

In some implementations, the first duty cycle produces a first ion energy distribution of the ions and, the second duty cycle produces a second ion energy distribution of the ions that is narrower than the first ion energy distribution.

In some implementations, the second voltage level is greater than the first voltage level.

In some implementations, the second frequency is greater than the first frequency.

It will be appreciated that the foregoing represents a summary of certain non-limiting implementations of the disclosure. Additional implementations will be apparent to those skilled in the art in accordance with the scope of the present disclosure.

### BRIEF DESCRIPTION OF THE DRAWINGS

FIG. 1 conceptually illustrates pulsed RF signals used in plasma processing operations, in accordance with implementations of the disclosure.

FIG. 2 conceptually illustrates various bias RF pulsing schemes incorporating non-sinusoidal waveforms, in accordance with implementations of the disclosure.

FIG. 3 is a conceptual graph illustrating ion flux versus energy for various bias RF signals applied in a plasma process, in accordance with implementations of the disclosure.

FIG. 4 conceptually illustrates benefits of applying non-sinusoidal waveforms in a pulsed bias RF signal, in accordance with implementations of the disclosure.

FIG. 5 conceptually illustrates a method for applying a non-sinusoidal waveform to a bias RF signal to achieve targeted ion energy characteristics, in accordance with implementations of the disclosure.

FIG. 6 conceptually illustrates an inductively coupled plasma system, in accordance with implementations of the disclosure.

FIG. 7 shows a control module 700 for controlling the systems described herein, in accordance with implementations of the disclosure.

### DETAILED DESCRIPTION

Implementations of the present disclosure provide capability in ion energy and ion mass selective etch for two or more materials of an etch stack with simultaneous control over high aspect ratio (HAR) etch rate and optimized iso/dense feature loading by utilizing both sinusoidal and custom/tailored RF waveforms in a multi-level pulsing (MLP) scheme for generating the bias RF signal. It should be appreciated that the present embodiments can be implemented in numerous ways, e.g., a process, an apparatus, a system, a device, or a method on a computer readable medium. Several embodiments are described below by way of example, without limitation.

Selectivity to materials is managed via controlling ion energies that are equal to or more than the etch threshold for that material. At the same time, optimizing the spread of the ion angular distribution at the higher ion energies enables ions to etch high aspect ratio features. The implementations of the present disclosure combine techniques to control both etch-threshold energy and ion angular spread for different materials in the same stack with minimal trade-off to etch metrics by utilizing a conventional sinusoidal bias RF waveform and customized RF waveform with tunable voltage, duty cycle, width and amplitude of positive raise.

Current state-of-the-art technology utilizes sinusoidal waveforms for both continuous wave (CW) high voltage bias pulsing and multilevel pulsing (MLP) with single or mixed frequencies and two to four level pulses.

Implementations of the present disclosure combine both sinusoidal MLP schemes and custom RF waveforms for part of the bias level cycles. The custom waveform helps modulate (e.g. lower or raise) and control the ion energy levels specific to an etch threshold, and enables control over the ion angular distribution. And the multi-level pulsing with sinusoidal RF waveforms helps control the ion angular spread at higher energy operation. By varying the duty cycle, number of levels, operating voltage and waveforms, control over the etching outcome is achieved.

The innovative mixing of both sinusoidal and custom non-sinusoidal RF bias waveforms in a multi-level pulsing scheme enables control over ion energy and ion mass dependency of etch to obtain better selectivity when multiple materials are involved in the feature over a range of aspect ratios.

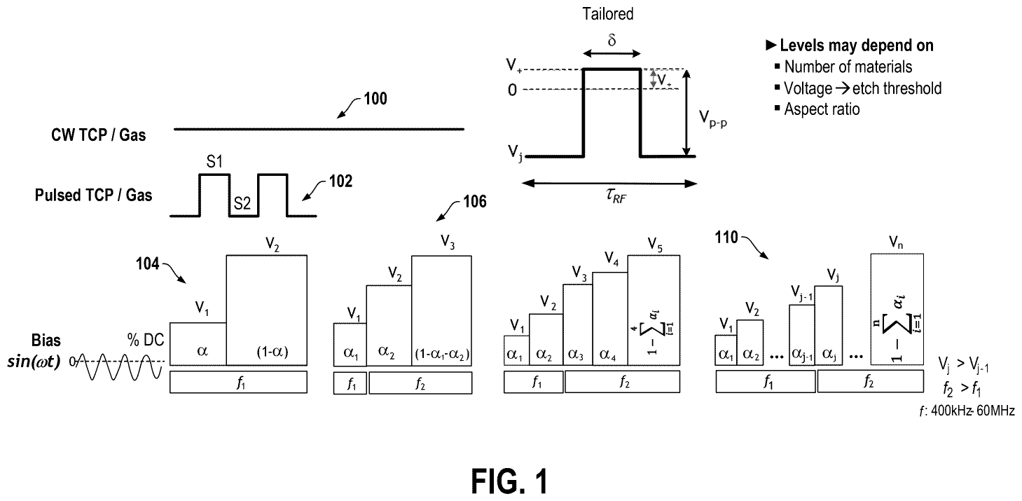

FIG. 1 conceptually illustrates pulsed RF signals used in plasma processing operations, in accordance with implementations of the disclosure.

In some implementations, plasma is generated using an inductively coupled plasma (ICP, or transformer coupled plasma (TCP)) system. Examples of ICP/TCP systems include the Kiyo® systems manufactured by Lam Research Corporation, which include systems capable of performing reactive ion etch and atomic layer etch. In an example ICP/TCP system, a source RF signal is applied to a TCP coil, thereby inductively coupling power into a process region of a process chamber to generate a plasma in the process region that is over a substrate (e.g. a wafer) undergoing processing. In some implementations, the source RF signal is a continuous wave (CW) source RF signal that is not pulsed, but has a substantially constant voltage (amplitude) such as that represented by the line 100 showing voltage versus time. In other implementations, the source RF signal is pulsed, and may have a voltage pulsing scheme such as that shown by the curve 102. For example, the source RF signal can be configured to alternate between a high voltage pulse state S1 and a low voltage pulse state S2 as conceptually shown.

A bias RF signal is applied to a lower electrode over which the substrate is disposed. Broadly speaking, the application of the bias RF signal is configured to drive ions generated in the plasma across the plasma sheath and accelerate them towards the substrate surface to carry out etching of the substrate surface. The bias RF signal can be a pulsed signal in which a sinusoidal waveform is pulsed at multiple voltages and further, the frequency of the sinusoidal waveform may vary for different pulse duty cycles of the pulsing scheme.

For example, a bias RF pulse scheme 104 conceptually illustrates a pulsing scheme consisting of a first pulse duty cycle at a voltage V1 that alternates with a second pulse duty cycle at a voltage V2. The underlying waveform is a sinusoidal waveform at a frequency f1 (e.g. 400 kHz to 60 MHz).

Additional examples of bias RF pulsing schemes are shown having additional pulse voltage levels and frequencies. For example, in the bias RF pulsing scheme 106, the pulsing scheme consists of three states, including a first pulse duty cycle at a voltage V1, a second pulse duty cycle at a voltage V2, and a third pulse duty cycle at a voltage V3. During the first pulse duty cycle the signal has a frequency f1, while during the second and third pulse duty cycles the signal has a frequency f2.

In the bias RF pulsing scheme 108, the pulsing scheme consists of five states, including a first pulse duty cycle at a voltage V1, a second pulse duty cycle at a voltage V2, a third pulse duty cycle at a voltage V3, a fourth pulse duty cycle at a voltage V4, and a fifth pulse duty cycle at a voltage V5. During the first two pulse duty cycles the signal has a frequency f1, while during the third, fourth, and fifth pulse duty cycles the signal has a frequency f2.

In the bias RF pulsing scheme 110, there can be any number of pulse states as shown, and such pulse states may have various duty cycles as well as different frequencies.

In some implementations, successive pulse states within a single pulse cycle of a given RF pulsing scheme are configured to have increasing voltage levels. In other implementations, the voltage levels of the pulse states can vary in other ways. In some implementations, successive pulse states within a single pulse cycle are configured to have increasing frequencies when such frequencies change from one pulse state to the next within the cycle (e.g. in the above examples, f2>f1). In other implementations, the frequencies may vary in other ways (e.g. in the above examples, f2>f1).

In the bias RF pulsing described with reference to FIG. 1, the underlying waveforms are sinusoidal. However, as described in further detail below, further improvements are attainable through the use of custom/tailored non-sinusoidal waveforms.

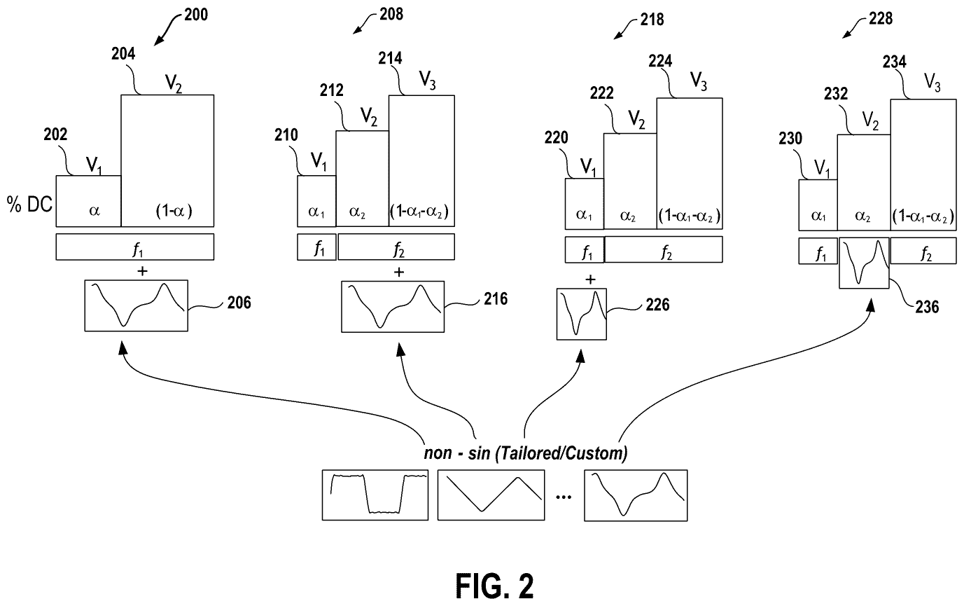

FIG. 2 conceptually illustrates various bias RF pulsing schemes incorporating non-sinusoidal waveforms, in accordance with implementations of the disclosure.

In an example of a bias RF pulsing scheme 200, the pulse cycle consists of two pulse states including a first pulse state 202 at a voltage V1 that alternates with a second pulse state 204 at a voltage V2. In some implementations, V2 is greater than V1. As indicated, the first pulse state 202 has a duty cycle α, and consequently the second pulse state 204 has a duty cycle 1-α. In some implementations, the underlying waveform consists of a sinusoidal waveform at a frequency f1 combined with a non-sinusoidal waveform 206. In other implementations, the underlying waveform does not include the sinusoidal waveform, but rather consists only of the non-sinusoidal waveform 206.

By way of example without limitation, examples of custom/tailored non-sinusoidal waveforms used in accordance with implementations of the disclosure can include any of the following and others not specifically described but known in the art: square waves, rectangle waves, trapezoid waves, triangle waves, sawtooth waves, etc. A non-sinusoidal waveform can also be generated by mixing two or more waveforms, including mixing two or more sinusoidal and/or non-sinusoidal waveforms which may have different frequencies, amplitudes, and/or other characteristics.

In another example of a bias RF pulsing scheme 208, the pulse cycle consists of three pulse states including a first pulse state 210 at a voltage V1, followed by a second pulse state 212 at a voltage V2, followed by a third pulse state 214 at a voltage V3. In some implementations, V3 is greater than V2, which is greater than V1. As indicated, the first pulse state 210 has a duty cycle α1, the second pulse state 212 has a duty cycle α2, and the third pulse state 214 has a duty cycle 1-α1-α2. In some implementations, the underlying waveform during the first pulse state 210 is a sinusoidal waveform at a frequency f1, and the underlying waveform during the second and third pulse states 212 and 214 consists of a sinusoidal waveform at a frequency f2 combined with a non-sinusoidal waveform 216. In other implementations, the underlying waveform during the second and third pulse states does not include the sinusoidal waveform, but rather consists only of the non-sinusoidal waveform 216. In some implementations, the voltages V2 and V3 of the second and third pulse states 212 and 214 are set to be equal, resulting in a two-state pulsing regime.

In another example of a bias RF pulsing scheme 218, the pulse cycle consists of three pulse states including a first pulse state 220 at a voltage V1, followed by a second pulse state 222 at a voltage V2, followed by a third pulse state 224 at a voltage V3. In some implementations, V3 is greater than V2, which is greater than V1. As indicated, the first pulse state 220 has a duty cycle α1, the second pulse state 222 has a duty cycle α2, and the third pulse state 224 has a duty cycle 1-α1-α2. In some implementations, the underlying waveform during the first pulse state 220 consists of a sinusoidal waveform at a frequency f1 combined with a non-sinusoidal waveform 226, and the underlying waveform during the second and third pulse states 222 and 224 is a sinusoidal waveform at a frequency f2. In other implementations, the underlying waveform during the first pulse state 220 does not include the sinusoidal waveform, but rather consists only of the non-sinusoidal waveform 226. In some implementations, the voltages V2 and V3 of the second and third pulse states 222 and 224 are set to be equal, resulting in a two-state pulsing regime.

In another example of a bias RF pulsing scheme 228, the pulse cycle consists of three pulse states including a first pulse state 230 at a voltage V1, followed by a second pulse state 232 at a voltage V2, followed by a third pulse state 234 at a voltage V3. In some implementations, V3 is greater than V2, which is greater than V1. As indicated, the first pulse state 230 has a duty cycle α1, the second pulse state 232 has a duty cycle α2, and the third pulse state 234 has a duty cycle 1-α1-α2. In some implementations, the underlying waveform during the first pulse state 230 is a sinusoidal waveform at a frequency f1, the underlying waveform during the second pulse state 232 consists of a non-sinusoidal waveform 236, and the underlying waveform during the third pulse state 234 is a sinusoidal waveform at a frequency f2. In other implementations, the underlying waveform during the second pulse state consists of a sinusoidal waveform mixed with the non-sinusoidal waveform 236.

In the above-described implementations, a single non-sinusoidal waveform is applied to one or more pulse states of a multi-state pulsing scheme. However, in some implementations, more than one non-sinusoidal waveform can be applied across different ones of the pulse states either as a substitute for a sinusoidal waveform or in combination with such a sinusoidal waveform.

Though in the above-described implementations bias RF multistate pulsing schemes have been described having two or three pulse states, it will be appreciated that in other implementations there can be more than three states. In such implementations, a given pulse state may employ a sinusoidal waveform, a non-sinusoidal waveform, or a mixed waveform consisting of a non-sinusoidal and sinusoidal waveform in combination. Furthermore, it will be appreciated that the particular voltage levels and frequencies of the various pulse states can vary in different implementations, similar to that described above with reference to FIG. 1.

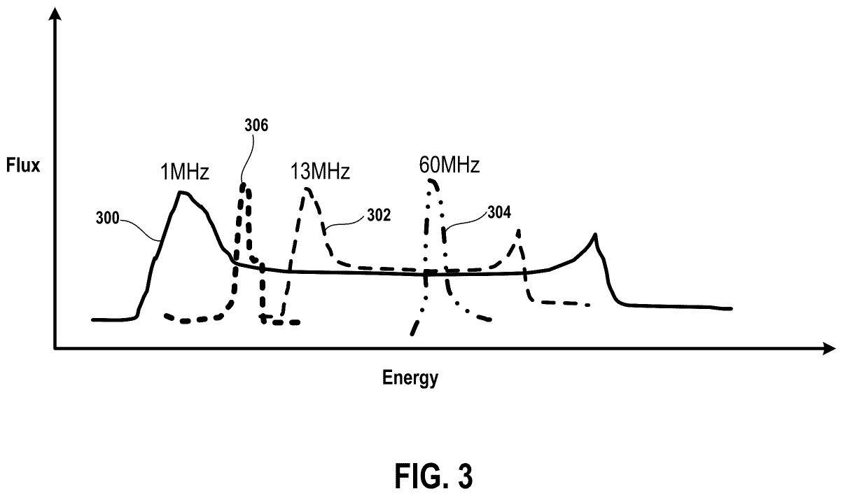

FIG. 3 is a conceptual graph illustrating ion flux versus energy for various bias RF signals applied in a plasma process, in accordance with implementations of the disclosure.

It will be appreciated that the illustrated graph is conceptual and provided by way of example for illustrating the benefits of using non-sinusoidal custom/tailored waveforms in accordance with implementations of the disclosure.

A continuing challenge in plasma processing is how to gain control of the ion angular distribution. Generally speaking, a narrow distribution of ion energies also produces a narrow ion angular distribution, so that more ions travel vertically with less loss along sidewalls of features being etched. As bias RF frequency increases, the ion energy distribution narrows, but the ion energy also increases. Thus, it has been a challenge to achieve narrow ion angular distribution without also requiring high energies, which may not be suitable for certain processes and may not enable selectivity for a given material.

For example in the illustrated graph, flux versus ion energy is conceptually illustrated for various frequencies. The curve 304 conceptually illustrates the ion energy distribution of ions accelerated using a relatively high frequency bias RF signal having a sinusoidal waveform (e.g. 60 MHz), whereas the curves 302 and 300 conceptually illustrate the ion energy distribution of ions accelerated using increasingly lower frequency bias RF signals (e.g. 13.56 MHz and 1 MHz, respectively). As can be seen from these curves, the ion energy distribution is narrow at a relatively high energy level, but becomes wider (typically exhibiting a bimodal distribution) at lower frequencies. Thus, it is a challenge to achieve narrow ion energy distributions (and narrow ion angular distribution) at lower frequencies.

However, by introducing non-sinusoidal waveforms in accordance with implementations described herein, it is possible to generate ions at lower energies while also providing a narrow ion energy distribution. One such example is conceptually shown by the curve 306, demonstrating narrow ion energy distribution in a low energy regime achieved through the use of non-sinusoidal waveforms as described herein. Thus, it is possible to gain control of ion angular distribution even at low energies, enabling better selectivity of the etch process.

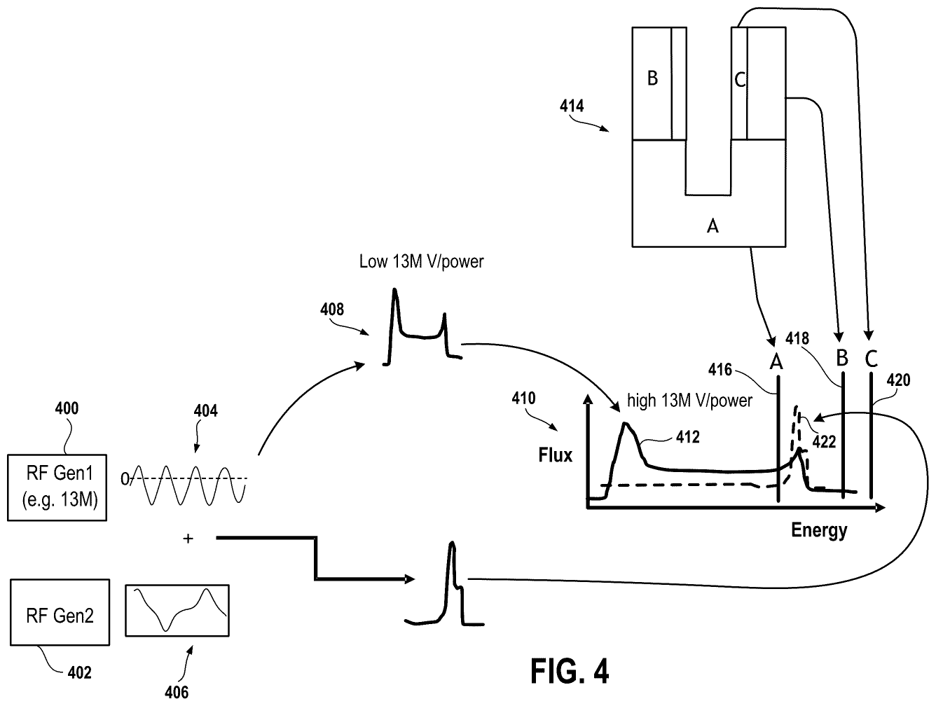

FIG. 4 conceptually illustrates benefits of applying non-sinusoidal waveforms in a pulsed bias RF signal, in accordance with implementations of the disclosure.

Under current state-of-the art etch processes, an RF generator 400 generates a sinusoidal waveform 404 (by way of example without limitation, at 13.56 MHz), which may be pulsed. The resulting ion energies (conceptually shown at reference 408) may not be sufficient to etch certain materials or etch to the bottom of certain high-aspect ratio features. Therefore, to increase the ion energies, DC power can be additionally applied to the RF signal to increase the ion energies. However, while this increases the ion energies, the distribution of the energies is also spread, resulting in the ion energy distribution shown by the curve 412.

Consider the case of a feature 414 (conceptually shown in cross-section) having materials A, B, and C. The energy thresholds for etching materials A, B, and C are conceptually shown in the energy versus flux graph 410 by the threshold lines 416, 418, and 420. It is desired to etch material A at the bottom of feature 414, while avoiding etching materials B and C, along the top surface of the substrate and sidewalls, respectively. Using the sinusoidal waveform 404 alone, applying high power enables some of the ions to have sufficient energy to etch material A. However, this is inefficient and throughput is low as only a small fraction of the ions have sufficient energy to etch material A, while a significant portion of the ions do not have sufficient energy to etch material A. Ion angular distribution is quite dispersed given the spread of the ion energies as shown by the curve 412, such that many ions will not penetrate downward into the feature 414, and are lost along the sidewalls. Applying greater DC power would increase the ion energies, but this would push the top end of the ion energies into regimes that may etch materials B and C, which is not desirable. Thus, the tradeoff for achieving higher energies in this manner is loss of selectivity to material A.

However, by introducing a non-sinusoidal custom waveform 406 produced by a second RF generator 402, as discussed above, then a narrow ion energy distribution shown by the curve 422 can be achieved. As has been noted, in some implementations, the non-sinusoidal waveform can be combined with, or replace, existing sinusoidal waveforms, during at least part of the pulse cycle. As shown by the curve 422, the ion energies produced are primarily concentrated at a level sufficient to etch material A, without significant generation of species that would etch materials B or C. Efficiency and throughput are enhanced as ion energies are focused beyond the threshold for material A. By applying non-sinusoidal custom waveforms in accordance with implementations of the disclosure, it is possible to gain control of the ion energy distribution and target a specific energy level to provide selectivity for a given material.

As noted above, ARDE continues to pose a challenge of how to increase the energy of ions that reach the bottom of HAR features. Lowered bias RF frequency coupled with pulsing of underlying sinusoidal waveforms has enabled the requisite spikes in voltage when the duty cycle turns on to enable acceleration of higher energy ions capable of driving down into the HAR features. However, control of angular spread of the incoming ion species remains a challenge, as many ions are lost on the sidewalls or fail to enter the HAR features at all. Another challenge is that there are iso and dense features, and different materials, such that the tradeoff is that if one is able to generate ions having sufficient energy to reach the bottom, then they tend to also etch the mask because of high energies or low selectivities to the mask.

However, by mixing custom waveforms with sinusoidal waveforms in pulsed bias RF signals, control over ion energy distribution is achieved both in terms of energy and distribution/spread. This enables targeting ion energies to achieve selectivity of etch. Without being bound by any particular theory of operation, it is nonetheless posited by way of explanation that the custom waveform is a different voltage waveform that changes how the ions travel through the plasma sheath and thereby changes the ion energy distributions. This enables tuning the sheath capacitance or resistance, and the ions behave differently enabling control over the ion energy distributions. So by changing the waveform, it becomes possible to tune the ion energy distribution to achieve a narrow distribution at a target energy level. Parameters of the bias RF waveforms such as non-sinusoidal/custom waveform selection, voltage, duty cycle, width and amplitude of positive raise, are tunable to provide a desired target energy level and ion energy distribution.

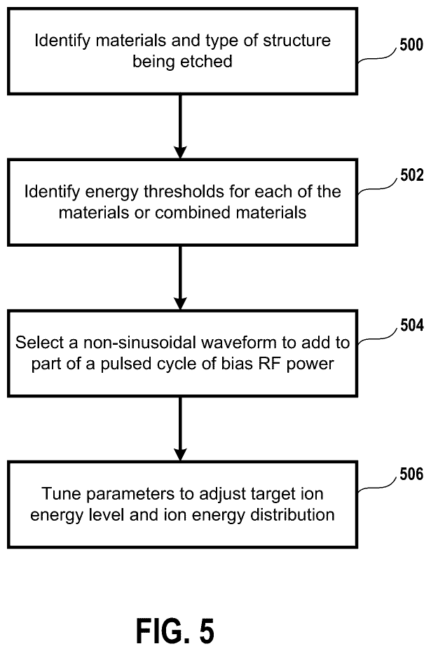

FIG. 5 conceptually illustrates a method for applying a non-sinusoidal waveform to a bias RF signal to achieve targeted ion energy characteristics, in accordance with implementations of the disclosure.

In some implementations, the method is implemented through a user interface of a controller/computer that enables control of operational parameters of a plasma processing system, including the parameters of the bias RF signal.

At method operation 500, the materials being etched and the type of structure being etched are identified. By way of example without limitation, the structure may be a stack, a via or trench, may have side materials, various layers, etc.

At method operation 502, the energy thresholds for each of the materials or combined materials (e.g. combined layers of materials) are identified.

At method operation 504, based on the energy thresholds of the materials, a non-sinusoidal waveform is selected to add to at least a part of a pulsed cycle of bias RF power. As described above, the non-sinusoidal waveform may be combined with a sinusoidal waveform in some implementations, or used alone in other implementations.

At method operation 506, the parameters of the bias RF signal are tuned to adjust the target ion energy level and ion energy distribution to their desired state. Examples of tunable parameters include the multi-level pulsing levels, the duty cycles of the pulses, voltage segregation in the pulse period, waveform tailoring (e.g. peak-to-peak voltage, width of positive raise, amplitude of positive raise), gas flow rate of etchant versus passivant.

In some implementations, at least a portion of method operations 502, 504 or 506 described above is performed automatically by the controller/computer in response to identification of the materials being etched and/or the type of structure being etched. For example, energy thresholds can be automatically determined, and predefined non-sinusoidal waveforms can be applied automatically, along with default parameters. In some implementations, the method operations 504 and 506 are performed manually by an operator through a user interface configured to enable the method operations 504 and 506 to be carried out in response to received input through the user interface.

While concepts described herein are applicable to etching of high aspect ratio features, they are also applicable to low aspect ratio etch processes such as mask open. For the selectivity and control of ion energies afforded by the present embodiments are also useful in such applications.

The concepts described herein are also applicable for atomic layer etch (ALE), in which typically the goal is to remove approximately a monolayer of material per ALE cycle. For example, a silicon ALE process typically employs fluorination for the activation step and an argon plasma for the removal step. However, if using, for example, a typical sinusoidal 13 MHz bias, there will be ion energy spreads due to the nature of the sheath dynamics and ion energy distribution resulting from the plasma sheath under such a 13 MHz bias. There will be some species at higher energies than what is actually needed for the material removal, so one will not have precise control over the etch-pulse cycle. However, by applying a non-sinusoidal waveform as described herein, it becomes possible to control and on-demand produce a certain ion energy using such a tailored waveform, enabling precise removal of the layer and better control over the etch-pulse cycle.

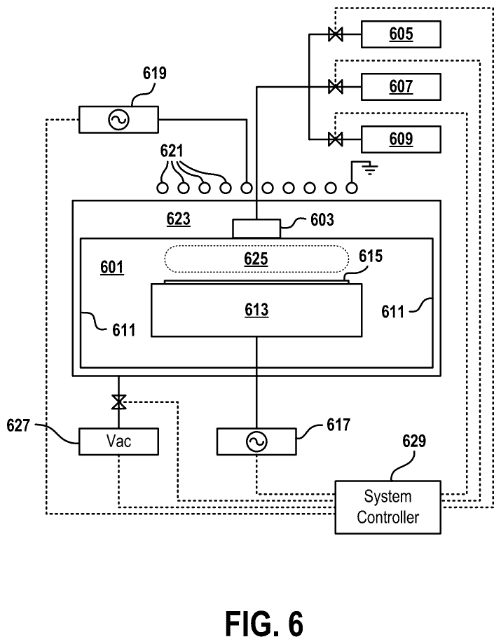

FIG. 6 conceptually illustrates an inductively coupled plasma system, in accordance with implementations of the disclosure.

Various implementations described herein may be performed in an inductively coupled plasma (ICP) system. An example ICP system or apparatus may include a chamber 601 having a gas injector/showerhead/nozzle 603 for distributing gases (605, 607, 609) (e.g. precursor, etchant, oxidant, purge gases, etc.) or other chemistries into the chamber 601, chamber walls 611, a lower electrode 613 for holding a substrate or wafer 615 to be processed which may include electrostatic electrodes for chucking and dechucking a wafer. The lower electrode 613 is heated for thermal control, enabling heating of the substrate 615 to a desired temperature. In some implementations, the lower electrode 613 may be electrically charged using an RF power supply 617 to provide a bias voltage in accordance with implementations of the disclosure. In some embodiments, lower electrode 613 may also be referred to as a chuck. The RF power supply 617 can be defined by one or more RF generators as needed to generate the bias RF signal in accordance with implementations of the disclosure.

An RF power supply 619 is configured to supply power to an RF antenna/coil 621, disposed over a dielectric window 623 to generate a plasma 625 in the process space over the substrate 615. In some implementations, the chamber walls are heated to support thermal management and efficiency. A vacuum source 627 provides a vacuum to evacuate gases from the chamber 601. The system or apparatus may include a system controller 629 for controlling some or all of the operations of the chamber or apparatus such as modulating the chamber pressure, inert gas flow, plasma power, plasma frequency, reactive gas flow (e.g., precursor, etchant, oxidant, etc.); bias power, temperature, vacuum settings; and other process conditions.

In some implementations, a system/apparatus may include more than one chamber for processing substrates.

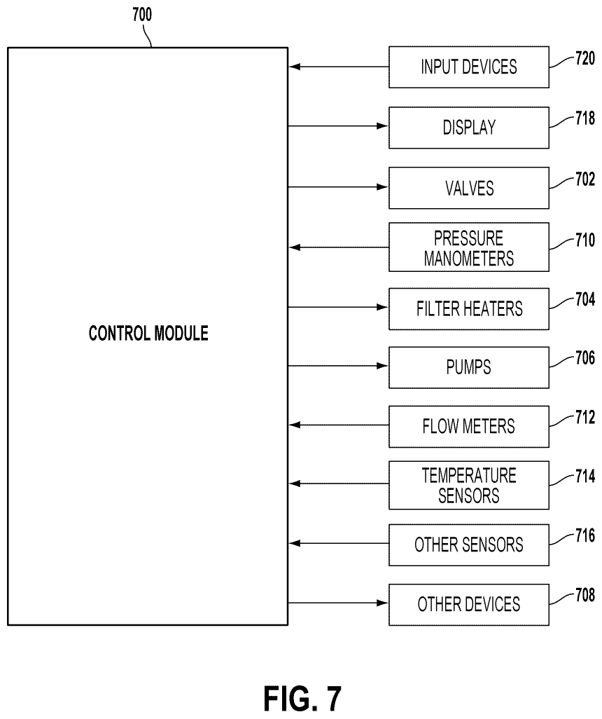

FIG. 7 shows a control module 700 for controlling the systems described herein, in accordance with implementations of the disclosure.

For instance, the control module 700 may include a processor, memory and one or more interfaces. The control module 700 may be employed to control devices in the system based in part on sensed values. For example, the control module 700 may control one or more of valves 702, filter heaters 704, pumps 706, and other devices 708 based on the sensed values and other control parameters. The control module 700 receives the sensed values from, for example only, pressure manometers 710, flow meters 712, temperature sensors 714, and/or other sensors 716. The control module 700 may also be employed to control process conditions during reactant delivery and plasma processing. The control module 700 will typically include one or more memory devices and one or more processors.

The control module 700 may control activities of the reactant delivery system and plasma processing apparatus. The control module 700 executes computer programs including sets of instructions for controlling process timing, delivery system temperature, pressure differentials across the filters, valve positions, mixture of gases, chamber pressure, chamber temperature, wafer temperature, RF power levels, wafer ESC or pedestal position, and other parameters of a particular process. The control module 700 may also monitor the pressure differential and automatically switch vapor reactant delivery from one or more paths to one or more other paths. Other computer programs stored on memory devices associated with the control module 700 may be employed in some implementations.

Typically there will be a user interface associated with the control module 700. The user interface may include a display 718 (e.g. a display screen and/or graphical software displays of the apparatus and/or process conditions), and user input devices 720 such as pointing devices, keyboards, touch screens, microphones, etc.

Computer programs for controlling delivery of reactant, plasma processing and other processes in a process sequence can be written in any conventional computer readable programming language: for example, assembly language, C, C++, Pascal, Fortran or others. Compiled object code or script is executed by the processor to perform the tasks identified in the program.

The control module parameters relate to process conditions such as, for example, filter pressure differentials, process gas composition and flow rates, temperature, pressure, plasma conditions such as RF power levels and the RF frequency, cooling gas pressure, and chamber wall temperature.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

Although the foregoing implementations have been described in some detail for purposes of clarity of understanding, it will be apparent that certain changes and modifications may be practiced within the scope of the disclosed implementations. It should be noted that there are many alternative ways of implementing the processes, systems, and apparatus of the present implementations. Accordingly, the present implementations are to be considered as illustrative and not restrictive, and the implementations are not to be limited to the details given herein.

1. A method for performing a plasma etch process in a process chamber, comprising:
applying a source radiofrequency (RF) signal to a top electrode of the process chamber;
applying a bias RF signal to a lower electrode of the process chamber;
wherein the bias RF signal has two or more pulsed duty cycles, including
a first duty cycle having a first sinusoidal waveform at a first frequency and pulsed at a first voltage level, and
a second duty cycle having a custom waveform pulsed at a second voltage level, the custom waveform consisting of a second sinusoidal waveform at a second frequency that is combined with a non-sinusoidal waveform.

2. The method of claim 1, wherein the source RF signal is configured to generate a plasma in a plasma process region disposed between the top electrode and the lower electrode.

3. The method of claim 2, wherein the bias RF signal is configured to accelerate ions from the plasma towards the lower electrode.

4. The method of claim 3,
wherein the first duty cycle produces a first ion energy distribution of the ions; and,
wherein the second duty cycle produces a second ion energy distribution of the ions that is narrower than the first ion energy distribution.

5. The method of claim 1, wherein the second voltage level is greater than the first voltage level.

6. The method of claim 1, wherein the second frequency is greater than the first frequency.

7. The method of claim 1, wherein the top electrode is configured to inductively couple power, or capacitively couple power, into the process chamber.

8. A method for performing a plasma etch process in a process chamber, comprising:
applying a source radiofrequency (RF) signal to a top electrode of the process chamber;
applying a bias RF signal to a lower electrode of the process chamber;
wherein the bias RF signal has two or more pulsed duty cycles, including
a first duty cycle having a sinusoidal waveform at a first frequency and pulsed at a first voltage level, and
a second duty cycle having a non-sinusoidal waveform at a second frequency and pulsed at a second voltage level.

9. The method of claim 8, wherein the source RF signal is configured to generate a plasma in a plasma process region disposed between the top electrode and the lower electrode.

10. The method of claim 9, wherein the bias RF signal is configured to accelerate ions from the plasma towards the lower electrode.

11. The method of claim 10,
wherein the first duty cycle produces a first ion energy distribution of the ions; and,
wherein the second duty cycle produces a second ion energy distribution of the ions that is narrower than the first ion energy distribution.

12. The method of claim 8, wherein the second voltage level is greater than the first voltage level.

13. The method of claim 8, wherein the second frequency is greater than the first frequency.

14. The method of claim 8, wherein the top electrode is configured to inductively couple power, or capacitively couple power, into the process chamber.

15. A system for performing a plasma etch process, comprising:
a process chamber;
a source radiofrequency (RF) generator that generates a source RF signal applied to a top electrode of the process chamber;
a plurality of bias RF generators that generate a bias RF signal applied to a lower electrode of the process chamber;
wherein the bias RF signal has two or more pulsed duty cycles, including
a first duty cycle having a first sinusoidal waveform at a first frequency and pulsed at a first voltage level, and
a second duty cycle having a custom waveform pulsed at a second voltage level, the custom waveform consisting of a second sinusoidal waveform at a second frequency that is combined with a non-sinusoidal waveform.

16. The system of claim 15, wherein the source RF signal is configured to generate a plasma in a plasma process region disposed between the top electrode and the lower electrode.

17. The system of claim 16, wherein the bias RF signal is configured to accelerate ions from the plasma towards the lower electrode.

18. The system of claim 17,
wherein the first duty cycle produces a first ion energy distribution of the ions; and,
wherein the second duty cycle produces a second ion energy distribution of the ions that is narrower than the first ion energy distribution.

19. The system of claim 15, wherein the second voltage level is greater than the first voltage level.

20. The system of claim 15, wherein the second frequency is greater than the first frequency.
